(19) United States
(12) Patent Application Publication
(10) Pub. No.: US 2023/0177231 A1
(43) Pub. Date: Jun. 8, 2023

(54) INTELLIGENT CALIBRATION OF SYSTEMS OF EQUATIONS WITH A KNOWLEDGE SEEDED VARIATIONAL INFERENCE FRAMEWORK

(71) Applicant: International Business Machines Corporation, Armonk, NY (US)

(72) Inventors: Julian Bertram Kuehnert, Nairobi (KE); Oliver Bent, Oxford (GB); Sekou Lionel Remy, Nairobi (KE); Aisha Walcott, Nairobi (KE); Charles Muchiri Wachira, Karatina (KE); Catherine H. Crawford, Bedford, NH (US)

(21) Appl. No.: 17/540,722

(22) Filed: Dec. 2, 2021

(51) Int. Cl. G06F 30/20; G06F 16/24

(52) U.S. Cl. CPC G06F 30/20; G06F 16/24

(57) ABSTRACT

A modeling problem can be received. A database of prior calibrated models can be searched to identify a similar problem having features similar to the received modeling problem. The modeling problem can be calibrated using information of the identified similar problem. The accuracy of calibrated modeling problem can be monitored. The modeling problem can be recalibrated until a performance criterion is met. Calibrated modeling problem can be stored in the database.

### BACKGROUND

The present application relates generally to computers and computer applications, and more particularly to optimization and dynamic modeling of physical phenomena.

Parameter optimization using Bayesian or Variational Inference (VI) methods can be used to tune established and validated physical models for complex systems under varying localized simulations. For example, such methods can be used to calibrate parameters (coefficients) of systems of differential equations. This methodology relies on process prior assumptions including initial conditions for the system as well as distributions for the parameters.

However, the noise in initial conditions and initial distributions for optimization can lead to erroneous outputs requiring time consuming human analysis. Moreover, the number of parameters in the physical model can make the tuning process less amenable to an optimized calibration procedure, again increasing the burden on humans for analysis. One such example comes from disease modeling with compartmental models (Susceptible-Exposed-Infectious-Recovered (SEIR)), a set of differential equations to model the infected, recovered, and not-survived for a given disease and population. The initial conditions and non-stationarity in parameter sets lead to suboptimal solutions over time, or divergence of optimal parameter sets. For example, converged results may produce wrong coefficients based on correct or incorrect initial conditions. As another example, time dependent errors can occur as the non-stationary nature of parameters may lead to modifying calibration from a time step perspective and potentially reseeding with new distributions or initial conditions. As yet another example, trajectories of loss function over time may show a calibration process reducing overall loss but not converging on a consistent solution because of initial conditions or distribution.

### BRIEF SUMMARY

The summary of the disclosure is given to aid understanding of a computer system and method of intelligent calibration, and not with an intent to limit the disclosure or the invention. It should be understood that various aspects and features of the disclosure may advantageously be used separately in some instances, or in combination with other aspects and features of the disclosure in other instances. Accordingly, variations and modifications may be made to the computer system and/or their method of operation to achieve different effects.

A method, in one aspect, can include receiving a modeling problem to calibrate. The method can also include searching a database of prior calibrated models to identify a similar problem having features similar to the received modeling problem. The method can also include calibrating the modeling problem using information of the identified similar problem. The method can also include monitoring the accuracy of calibrated modeling problem. The method can also include recalibrating the modeling problem until a performance criterion is met. The method can also include storing calibrated modeling problem in the database.

A system, in an aspect, can include at least one hardware processor and a memory device coupled with said at least one hardware processor. At least one hardware processor can be configured to receive a modeling problem to calibrate. At least one hardware processor can also be configured to search a database of prior calibrated models to identify a similar problem having features similar to the received modeling problem. At least one hardware processor can also be configured to calibrate the modeling problem using information of the identified similar problem. At least one hardware processor can also be configured to monitor the accuracy of calibrated modeling problem. At least one hardware processor can also be configured to recalibrate the modeling problem until a performance criterion is met. At least one hardware processor can also be configured to store calibrated modeling problem in the database.

A computer readable storage medium storing a program of instructions executable by a machine to perform one or more methods described herein also may be provided.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1 is a diagram illustrating an overview of calibrating an uncalibrated model of a dynamic system in an embodiment.

FIG. 2 is a diagram illustrating a system in an embodiment.

FIGS. 3A-3F illustrate a use case example in an embodiment.

FIG. 4 is a diagram illustrating a method in an embodiment.

FIG. 5 is a diagram showing components of a system in one embodiment that can intelligently calibrate models of dynamic physical phenomena.

FIG. 6 illustrates a schematic of an example computer or processing system that may implement a system according to one embodiment.

FIG. 7 illustrates a cloud computing environment in one embodiment.

FIG. 8 illustrates a set of functional abstraction layers provided by cloud computing environment in one embodiment of the present disclosure.

### DETAILED DESCRIPTION

New systems or models that model dynamic physical phenomena may require expert guidance to initialize calibration of models. For example, the calibration of model parameters of dynamical systems, e.g., described by differential equation, may need expert guidance to specify parameter ranges and prior distributions. A system, method and technique can be provided for assisted model parameter calibration with reduced need for expert validation and intervention. In an aspect, the system and/or method may reduce the conventional human-in-the-loop requirement. In another aspect, the system and/or method may incorporate non-utilized experience from previous calibrations. For example, information from prior calibrations using initial conditions and parameter distributions from other solved systems can be cataloged to help drive similar dynamic systems or models.

In one or more embodiments, an automated system and/or method can, given an uncalibrated model, identify similar calibration problems of previously studied models, and pull experience gathered from calibrating these similar calibration problems to calibrate a new problem to data, without the need to specify parameter ranges and priors. In an embodiment, calibrating of the new model need not be “locked into” the structure of the previously studied models. For example, referring to a pre-trained neural network, the newly calibrated model need not have the same neural network structure of similar previously studied models from which data can be learned. For example, the system and/or method in an embodiment may focus on understanding the parameters from the latent space representation (e.g., versus the outputs).

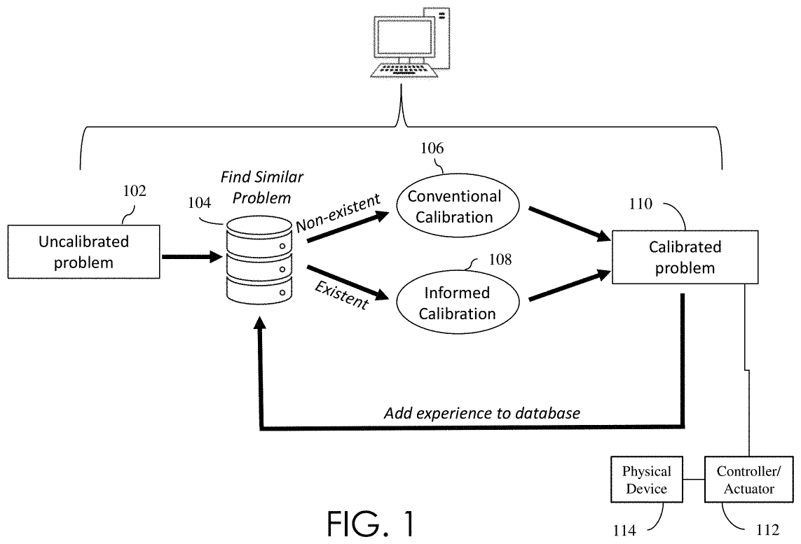

FIG. 1 is a diagram illustrating an overview of calibrating an uncalibrated model of a dynamic system in an embodiment. The components shown include computer-implemented components, for instance, implemented and/or run on one or more hardware processors, or coupled with one or more hardware processors. One or more hardware processors, for example, may include components such as programmable logic devices, microcontrollers, memory devices, and/or other hardware components, which may be configured to perform respective tasks described in the present disclosure. Coupled memory devices may be configured to selectively store instructions executable by one or more hardware processors.

A processor may be a central processing unit (CPU), a graphics processing unit (GPU), a field programmable gate array (FPGA), an application specific integrated circuit (ASIC), another suitable processing component or device, or one or more combinations thereof. The processor may be coupled with a memory device. The memory device may include random access memory (RAM), read-only memory (ROM) or another memory device, and may store data and/or processor instructions for implementing various functionalities associated with the methods and/or systems described herein. The processor may execute computer instructions stored in the memory or received from another computer device or medium.

An uncalibrated problem 102 can be received. For example, the uncalibrated problem 102 can include an algorithmic problem description provided by a single script file or a composition of multiple script files in a given programming language as well as the initial problem configuration including, for example, a set of default parameter values provided in a file format such as JavaScript Object Notation (JSON), comma-separated values (CSV), or text (TXT), or another format.

Similar problems can be defined or identified, for example, based on searching for prior calibrated problems, e.g., stored on a storage device 104. In an embodiment, to define or identify similar calibration problems, a processor initially creates a mapping between parameter sets and associated error values, e.g., collected in the initial iterations of the calibration process in which an objective function evaluates the model performance. A normalization of the parameter and error values may be applied to allow comparability between different calibration problems as well as projection of the parameter space into a low dimensional space reducing the degree of freedom using, for example, Proper Orthogonal Decomposition (POD). The mapping can be performed by clustering model inputs, including for example, initial conditions, parameter values, sensitivities, against the model outputs, represented for example by the error values, using algorithms such as K-Means or Gaussian Mixture Models (GMM). A database may store or contain previously calibrated problems provided in form of an experience vector/array containing the mappings between model inputs and model outputs, analog to the mapping of the current calibration problem, as well as any additional parameters which are not included in the mappings. Subsequently, comparing the current mapping with a catalogue of previous mappings, and using similarity metric of a probabilistic method (like Kullback-Leibler (KL)) or Euclidian distances, the processor can define that this calibration has been previously performed if the metric value is less than an epsilon and the processor can access the previously learned best parameter values. For instance, the processor compares the current mapping with a catalogue of previous mappings. Comparing can include computing a similarity metric, using a probabilistic method such as but not limited to, Kullback-Leibler (KL) divergence, between the current mapping and a catalogue of previous mappings. If the similarity metric value is less than an epsilon, e.g., a threshold value, the processor can define that this calibration has been previously performed. For instance, those previous mappings having a similarity metric less than an epsilon can be identified as similar calibration problems. The processor can access those identified calibration problems and extract the parameter values from those problems as the previously learned best parameter values.

At 106, in case no similar problem is found, a “conventional” calibration can be carried out to create a calibrated problem 110. For example, ranges of the model parameters which are to be calibrated are defined using prior knowledge on valid values for example from literature or from an experienced human expert. For calibrating the model, the parameter space can be searched to find sets of parameters which generate model prediction that reproduces observations within a given error bound. The search can be conducted using intelligent sampling such as Bayesian optimization. The calibrated problem 110 can be stored in a database of previous mappings.

At 108, in case a similar problem is found, informed calibration can be performed, for instance, leverage the experience in modeling the current problem to create a calibrated problem 110. In an embodiment, the experience vector may be used as a characterization of previous calibration problems, containing ranges of initial conditions, distributions of model parameters, their relative sensitivities, and the associated mappings to model outputs represented, for example, by the error values of the objective function which are stored in normalized and reduced form with similar degree of freedom as the projection of the current calibration problem, for example, described above. The similarity of calibration runs can then be evaluated, for example, by measuring the Euclidian distance between the clustered data point of the mappings in the experience vector or other probabilistic measures such as Kullback-Leibler (KL) divergence between the features in the experience vectors. As a similar previous calibration problem is determined within a threshold distance, the experience vector of this problem can be projected to the space of the current problem to leverage the previously learned ranges of initial conditions, parameter distributions and sensitivities for the purpose of bootstrapping previous calibration runs from other experiments to new ones. The calibrated problem 110 can be stored in a database of previous mappings. In an embodiment, the calibrated problem 110, for example, a model, can be run (e.g., a computer processor may run the model with input data). In an embodiment, an output generated by the model can automatically drive a controller or an actuator 112 to control a physical device 114. For instance, the calibrated problem 110 can be a disease modeling problem which may predict a disease transmission or progression rate or the like. Based on the prediction, a controller 112 may automatically trigger a physical or mechanical device, for example, which can include an air filtration system, space sanitization system (e.g., automatic sprays or radiations, taking into consideration safeness, and/or others), to operate or engage.

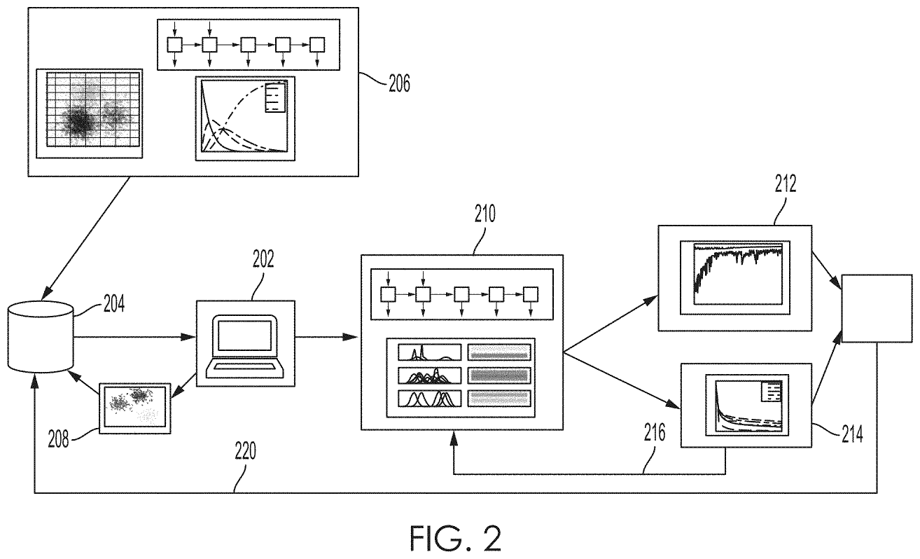

FIG. 2 is a diagram illustrating a system in an embodiment. The system can include one or more computer processors or hardware processors and one or more storage devices. A system may use information generated within and by various calibration methods, initial conditions and parameter distributions to intelligently rule out model configurations and associated results. For example, a set of prior initial conditions, parameter distributions and calibration outcomes for systems of equations (e.g., SEIR, MSEIR epidemiological compartmental models), which have been created can be utilized, all resulting in model predictions within an acceptable prediction error. The prior initial conditions and parameter distributions and results can be cataloged using statistical descriptions such as clustering with corresponding results or loss functions for the various systems of equations. A processor can use one or more standard statistical algorithms, for example clustering with K-Means or Gaussian Mixture Models (GMM) or Kullback-Leibler (KL) divergence, and provided software, such as but not limited to, statistical software for spreadsheet program, and/or existing machine learning library for predictive analysis, to build consistent statistical information about provided model configuration across different calibration problems to compare using known distance measures to find analog initial conditions and parameter distributions for a given system of differential equations and corresponding successful variational inference algorithm/method and seeding parameter distributions. If a similar enough initial condition of a previously calibrated problem for desired system of equations is found along with best initial seeds producing desired accuracy and uncertainty, a processor may choose such methods and distributions for additional calibrations and simulations.

A processor 202 may generate a catalog and store it on a storage device 204. For example, catalog generation can use statistical description of initial conditions and calibrated model results or loss functions with parameter distributions 206. This can be extended to multiple calibration methods for a single model and given initial conditions and parameter distributions.

The processor 202 may perform a search or lookup to compare initial conditions, parameter distributions and associated loss functions 208, e.g., via statistical modeling such as clustering techniques between model inputs and outputs, to guide new calibration problems with similar system of differential equations by using input distributions of initial conditions and parameter sets which decreased error of objective functions in previous calibration problems. In an embodiment, the initial conditions from previous calibration problems can potentially be reused as well as previous parameter sets (or the projection thereof). By way of example, initial conditions can be the number of infectious persons at the start time of the dynamic modeling.

The processor 202 may perform a calibration with multiple algorithms approaches and multiple distributions 210. In an embodiment, this can include reduction techniques of the free parameters including Sobol sensitivity analysis. The Sobol index is a variance-based measure of sensitivity. Sobol sensitivity indices quantify how much of the total variance of the model output each uncertain parameter (or input) is responsible for. The first-order Sobol index is a variance based method of sensitivity analysis and looks at the contribution of each model parameter to the total model output uncertainty. As such an ordering of each parameter by Sobol index and subsequent rejection of parameters with low contribution may increase the efficiency of the calibration process through reducing the size of the calibration parameter set. The Sobol index allows for analyzing parameter importance.

The processor 202 may monitor the calibration process for convergence shown at 212. The processor 204 may also test with historical results and tracking loss functions and/or L2 norms for performance, e.g., for accuracy and/or uncertainty, as shown at 214.

The processor 202 may also reset or reseed initial conditions 216 and perform recalibrating with new methods or parameter distributions when the test with historical results 214 indicates suboptimal solutions or divergence of optimal parameter sets. The calibration of a model at 212, for example, which meet the test satisfaction (e.g., based on a threshold) can result in a new calibrated model 218. The calibrated parameters and information of the calibration process resulting in the new model 218 can be added to the collection or prior calibrated models, for example, stored in 204. For example, the processor may automatically collect initial conditions, algorithms, distributions, and results associated with the new model 218 into catalog stored in storage device 204, for example, as shown by the arrow at 220.

In an embodiment, the system can be deployed on a hybrid-cloud hosted system, for example, which decision makers can sign in for credentialled access with policy makers. In an embodiment, the system can be provided for decision-support as a service, which may be deployed and used within various organizations such as in public and/or private sector. In an embodiment, a browser access to a website for the system can be provided for modeling.

In an embodiment, if no similar enough initial conditions for a desired system of equations is available, a processor may start a calibration process with given initial condition and, for example, preselected or user selected algorithm or method and distributions of parameters. In such embodiment, the calibration can be enhanced with adding multiple algorithms or methods as well as distributions to determine whether methods and distributions converge to similar parameters and whether parameters applied to historical data results in desired accuracy and/or uncertainty.

In another embodiment, the trajectories of loss functions in the calibration process with various algorithms and methodologies can be used to determine, either with human in the loop visualization or by automated detection with thresholding, which algorithms may produce the best results.

In another embodiment, leveraging historical data and tracking errors (e.g., L2 norms), either with human in the loop visualization or by automated detection, the calibration process may be processed with an additional time component, for instance resetting the initial conditions with the output of a simulation from calibration when an error threshold is reached. That historical data with error tracking can also be used to advise if any calibration method and set of initial parameter distributions will result in an accurate model alerting that the initial conditions themselves may be inaccurate.

In another embodiment, the results of calibrations and simulations when compared to historical data can be automatically generated and cataloged in the statistical methods described above to continually build the knowledge catalog of information for improved calibration and uncertainty results.

A system, in an embodiment, catalogs previous results of parameter calibration of systems of differential equations according to statistical features in the initial conditions, initial parameter distribution and corresponding calibration and model simulation results. For example, the system may characterize the calibration problem by statistical features of model inputs and outputs, for example, by clustering the initial conditions and parameter sets against the loss values of the objective function. Statistical features can be extracted from the mapping between inputs (initial conditions, parameter distributions) and outputs (calibration results, e.g., error or loss, or simulation result). The system, in an embodiment, can monitor the outputs of multiple calibration algorithms implemented with sampling methods such as, for example, Gradient Descent, Hamiltonian Monte Carlo, or Gaussian Processes, and initial parameter distributions, in terms of loss function to determine which combination of algorithm and distributions are best candidates based on a given selection criteria.

In an embodiment, a combination of historical data can be used to build a calibration simulation (e.g., model) with given initial conditions. The built calibration simulation can be evaluated for accuracy and uncertainty with a different subset of the historical data to track errors to automatically determine if any calibration algorithm will work for a given set of initial conditions or if the initial conditions may not be feasible for the set of differential equations.

In an embodiment, a combination of historical data can be used to build a calibration simulation with a given set of initial conditions, which can be evaluated for accuracy and uncertainty with a different subset of historical data to track errors and alert if the initial conditions for the calibration should be reset with outputs of a calibrated simulation at specified time intervals to improve accuracy and uncertainty.

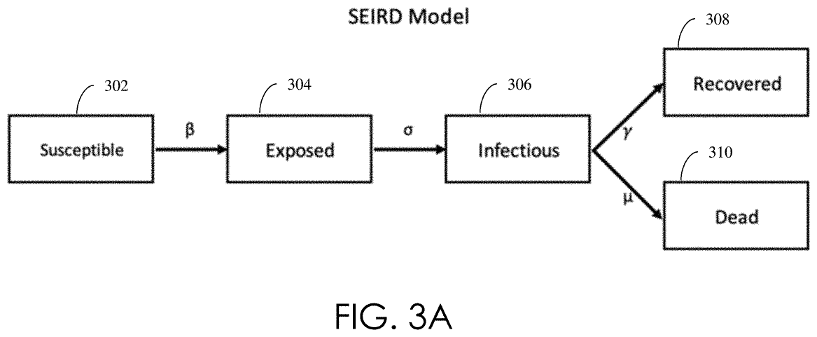

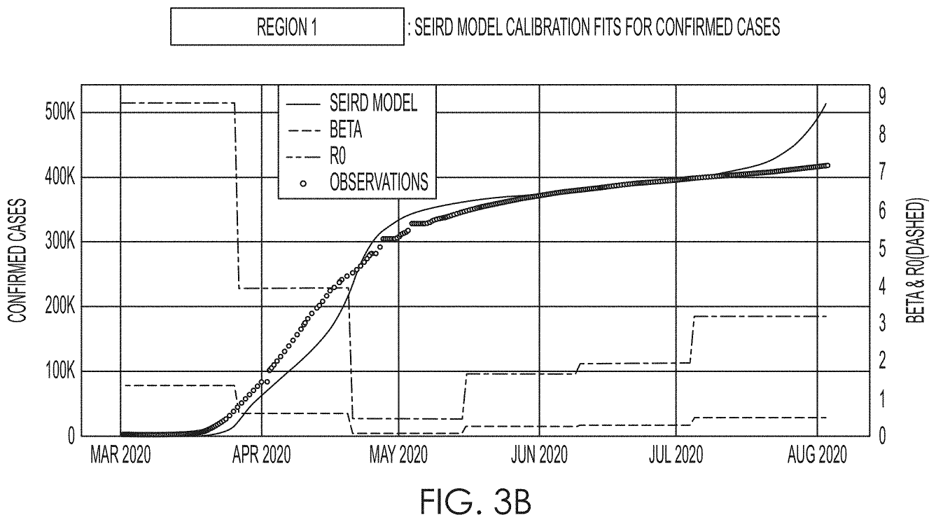

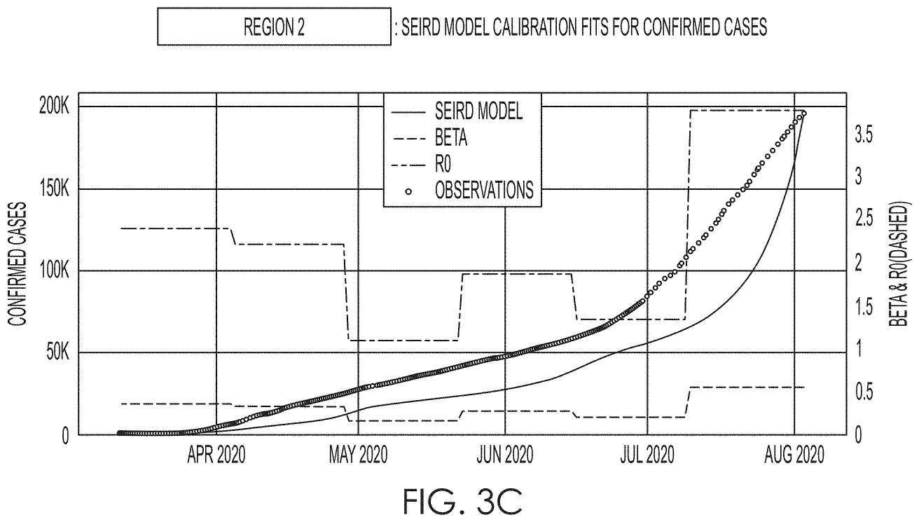

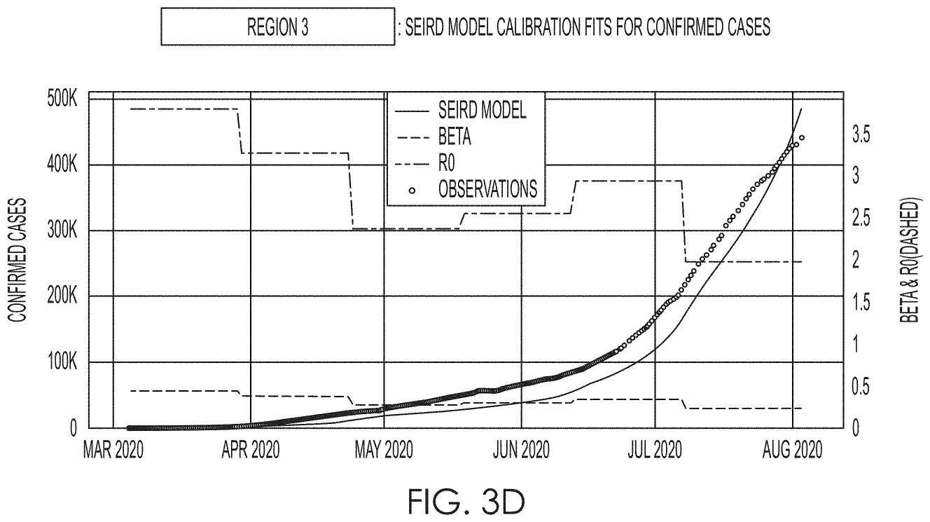

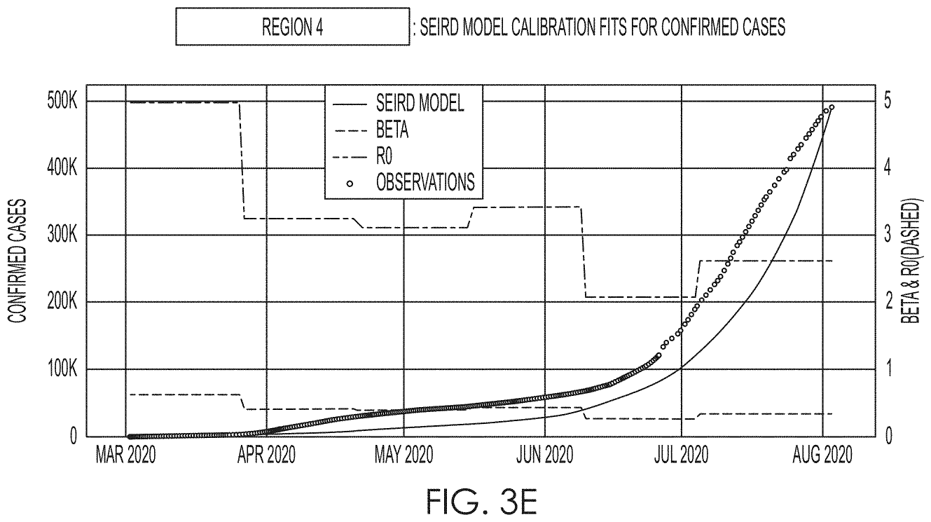

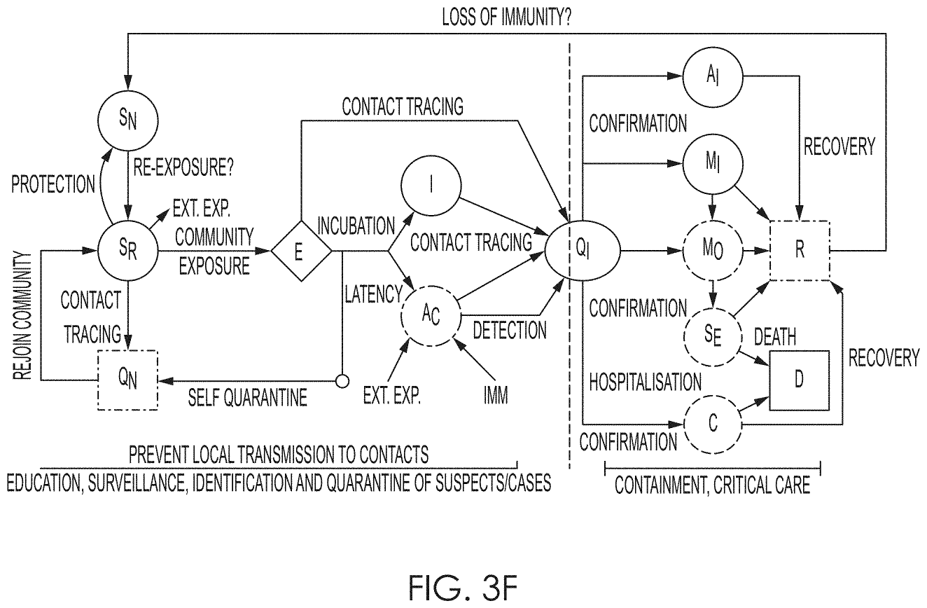

In an embodiment, the system provides an automated calibrations and simulations for model building based on prior calibrated models and their characteristics. FIGS. 3A-3F illustrate a use case example in an embodiment. Given a dynamic model description (e.g., SEIRD model) along with data for multiple locations (e.g., regions of a country), a processor can generate a region level calibration by steering the parameter values based on gathered experience when moving to a new location. Similarly, if one were to add in a different dynamic structure, the processor can automate similarities in this structure to steer the re-calibrations for all states. FIG. 3A shows an initial dynamic system, for example, a SEIRD model. The model parameterizes the relationships of susceptible 302, exposed 304, infectious 306, recovered 308 and not-survived 310 associated with a disease. Consider that there are multiple related problems in multiple locations, e.g., different regions of a country. FIGS. 3B, 3C, 3D and 3E show performance on separate problems steered through the calibration process. For example, FIG. 3B shows SEIRD model calibration fits for confirmed cases in region 1; FIG. 3C shows SEIRD model calibration fits for confirmed cases in region 2; FIG. 3D shows SEIRD model calibration fits for confirmed cases in region 3; and FIG. 3E shows SEIRD model calibration fits for confirmed cases in region 4. FIG. 3F shows a new dynamic model structure. The new dynamic model structure illustrates a comprehensive model for SARS-CoV-2 in a new region. In this example model, the nodes of the structure represent groups of people. For instance, Sn can represent a group of people who are newly susceptible to the given disease; Sr can represent a group of people who are re-exposed; Qn can represent a group of people who are quarantined; I can represent a group of people who are infected; Ac can represent a group of people who are asymptomatic; E can represent a group of people who are exposed; Mx can represent a group of people who have mild symptoms; Sx can represent a group of people who have severe symptoms; C can represent people who are in critical care; R can refer to a group of people who have recovered; and D can refer to a group of people who do not recover. The edges connecting the nodes represent the parameters that are to be learned.

In an embodiment, a method can include the following processing. Previous results of model parameter calibration can be cataloged according to statistical features in the initial conditions, initial parameter distribution and corresponding calibration and model simulation results. Given an uncalibrated model, similar calibration problems of previously studied models can be identified based on the statistical features. Experience gathered from calibrating similar problems in form of initial conditions, parameter distributions and associated loss functions can be pulled to calibrate a new problem to data, without the need to specify parameter ranges and prior distributions. If no similar calibration problem has been cataloged, the calibration of the new problem can be performed using multiple calibration algorithms and initial parameter distributions to determine the best combination thereof with respect to the loss function. Results can then be cataloged according to statistical features.

In an aspect, learning from different models based on their similarity in statistical representation of model structure and initial inputs can allow for independence from potentially flawed or non-converged model outputs. Further, defining the similarity based on model structure and initial inputs can lead to a new representation of similar models which can allow for transferring experience of calibration processes across models which are similar in a non-obvious way, and may be applied in unrelated domains.

In an embodiment, a system and/or method can use statistical methods to analyze calibrated models and response to receiving a new uncalibrated model to be calibrated, the system and/or method may use the statistical inferences learnt from other calibration episodes to calibrate the new model. In an aspect, the system and/or method may use multiple calibration algorithms and multiple initial parameters to calibrate a model that lacks similarity to the already existing models. The system and/or method may provide for categorizing the new model problem space based on the existing historical calibration problem catalogues. In an aspect, this ensures that more accurate calibration parameters can be obtained from this wide catalogue. In an aspect, the system and/or method can be used to calibrate many uncalibrated models even the ones whose problems have not been catalogued by use of multiple calibration algorithms and initial conditions.

In an aspect, the system and/or method can handle dynamical system models that represent the evolution of a physical phenomenon, and where even the parameters can change over time. Similar problems can be defined by the model structures themselves and the experience, quantified history, of the calibration process on a previous problem. The system and/or method may use a dynamic knowledge catalog and probabilistic similarity measure applied to dynamic systems models to determine problem similarity. The system and/or method may use an experience vector distribution. defining the similarity of problems by the model structures themselves and the learned calibration experience via statistical features. In an aspect, this makes the system and/or method suitable to a wide range of applications across different domains and enables transfer of knowledge across models which are non-obviously related. For example, by using statistical features stored in an experience vector, the system and/or method may be able to transfer learned knowledge of the calibration process between a wide variety of different dynamical models and need not be constrained on a specific model structure.

In an embodiment, in calibrating a new problem, the system and/or method can provide guidance in selecting calibration methods and defining parameter ranges, by experience learned from previous calibration of problems, which are similar in their calibration process. Experience and knowledge from calibrated models even from different applications or domains can be used.

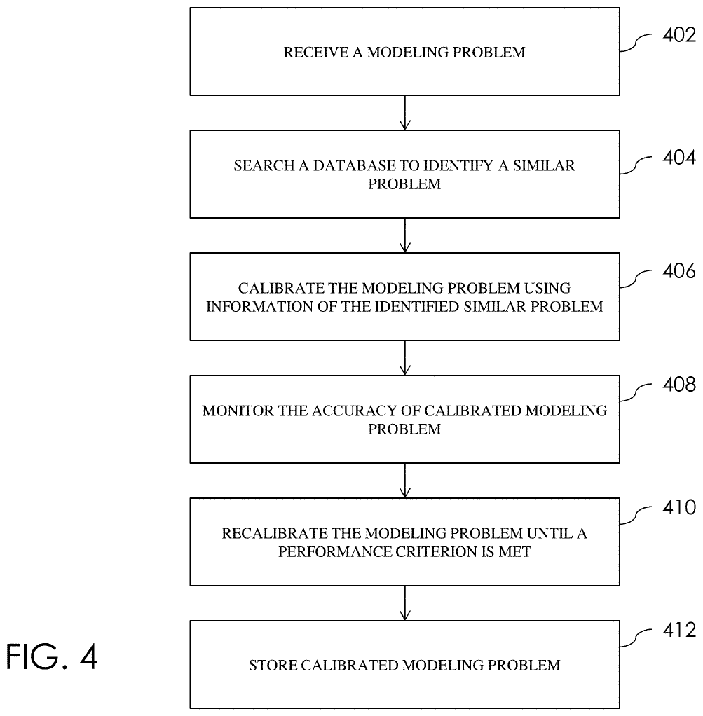

FIG. 4 is a flow diagram illustrating a method in an embodiment. One or more hardware processors can run or implement the method described herein. At 402, a modeling problem to calibrate can be received. At 404, a database of prior calibrated models can be searched to identify a similar problem having features similar to the received modeling problem. In an embodiment, the features can be statistical features associated with prior calibrated models. Similarity can be determined based on the features meeting a similarity threshold.

At 406, the modeling problem can be calibrated using information associated with the identified similar problem. For instance, the information can include statistical description of initial conditions and calibrated model results with parameter distributions. Calibrating can include performing a parameter reduction technique.

At 408, the accuracy of calibrated modeling problem can be monitored. For example, monitoring can include monitoring for convergence to an error threshold. Monitoring can also include testing with historical results and tracking loss functions to determine performance of the calibrated modeling problem.

At 410, for example, based on monitoring if the calibrated modeling problem does not meet a performance criterion, the modeling problem can be recalibrated until a performance criterion is met. A performance criterion, for example, can include a degree of accuracy and/or uncertainty.

At 412, the calibrated or recalibrated modeling problem can be stored or cataloged in the database. For example, the initial conditions and parameter distributions of the modeling problem can be stored. The next time another uncalibrated modeling problem is received for calibration, the newly added information of the modeling problem can also be searched as part of the prior calibrated modeling problems.

The method can also include generating a database of the prior calibrated models, the database storing statistical description of initial conditions and calibrated model results with parameter distributions associated with each of the prior calibrated models. The method can provide for improvements in building models of dynamic physical phenomena, e.g., improve the speed of building such models, such as improve computational processing speed of a computer processor and/or reduce processing power for building such models. The output from running a dynamic physical model can also be used to drive or automate a physical actuator or device and/or act as an automatic control for activating an actuator or device.

For example, a calibrated model can predict the dynamics of real-world problems such as disease modeling, which predictions can help in decision making, e.g., for the early implementation of policies to prevent disease transmission. For example, based on running a calibrated model, for example, a disease model, and the output generated by such a disease model, one or more measures can be triggered or deployed. Examples of triggered measures can include, but not limited to, distribution of mosquito nets (e.g., insecticide-treated nets), residual spraying, vaccinations. Other measures can include limiting of maximum number of persons in a public space or a train or another public transportation vehicle. In some aspects, such measures can be automatic, for example, automatically trigger or actuate a mechanical or physical device for early prevention of transmission. For example, a disease model output can trigger an air filtration system to run automatically in a space. As another example, a physical system or device monitoring a number of persons in a space can be automated to control the maximum occupancy level of a space, for example, an entry may be automatically blocked. Automated alarms can be sent, e.g., which can include sending alarms to mobile devices. Display signs can be automatically triggered to display current occupancy levels. Considering a model in another domain, e.g., one which predicts weather related events, an output prediction of such a model may automate early warning or intervention for natural hazards such as floods. An example of an action which may be automatically triggered may include closing of flood barriers (e.g., storm surge barriers) automatically. For example, such barriers can be automatically actuated to open or close. Another example of an action may include redirecting traffic to protect goods and people.

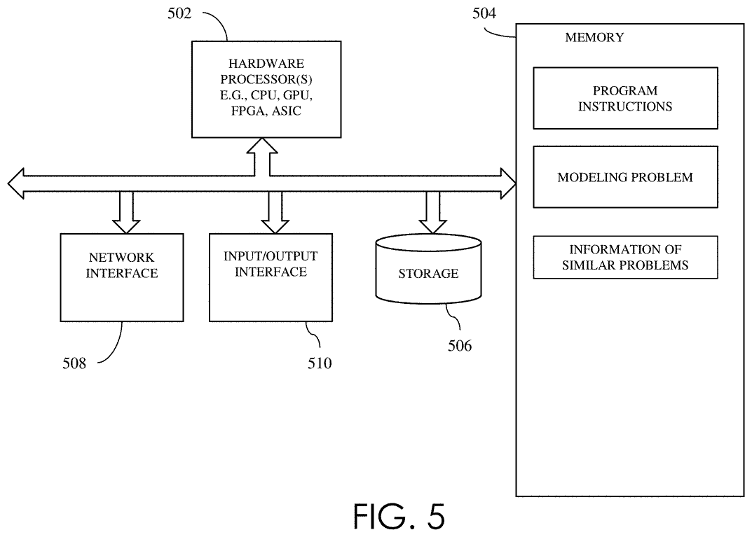

FIG. 5 is a diagram showing components of a system in one embodiment that can intelligently calibrate models of dynamic physical phenomena. One or more hardware processors 502 such as a central processing unit (CPU), a graphic process unit (GPU), and/or a Field Programmable Gate Array (FPGA), an application specific integrated circuit (ASIC), and/or another processor, may be coupled with a memory device 504, and generate a calibrated model intelligently based on prior calibrated model information. A memory device 504 may include random access memory (RAM), read-only memory (ROM) or another memory device, and may store data and/or processor instructions for implementing various functionalities associated with the methods and/or systems described herein. One or more processors 502 may execute computer instructions stored in memory 504 or received from another computer device or medium. A memory device 504 may, for example, store instructions and/or data for functioning of one or more hardware processors 502, and may include an operating system and other program of instructions and/or data. One or more hardware processors 502 may receive input, which may include information about a modeling problem for calibration. At least one hardware processor 502 may search a database of prior calibrated models to identify a similar problem having features similar to the received modeling problem. At least one hardware processor 502 may calibrate the modeling problem using information of the identified similar problem. At least one hardware processor 502 may monitor the accuracy of calibrated modeling problem. At least one hardware processor 502 may recalibrate the modeling problem until a performance criterion is met. At least one hardware processor 502 may store calibrated parameters of the modeling problem in the database. In one aspect, generated or cataloged calibrated model information may be stored in a storage device 506 or received via a network interface 508 from a remote device, and may be temporarily loaded into a memory device 504 for generating a new calibrated model. The learned or calibrated model and its statistical features or information may be stored on a storage device 506 and or communicated to a remote device via a network interface 508. For instance, one or more hardware processors 502 may be coupled with interface devices such as a network interface 508 for communicating with remote systems, for example, via a network, and an input/output interface 510 for communicating with input and/or output devices such as a keyboard, mouse, display, and/or others.

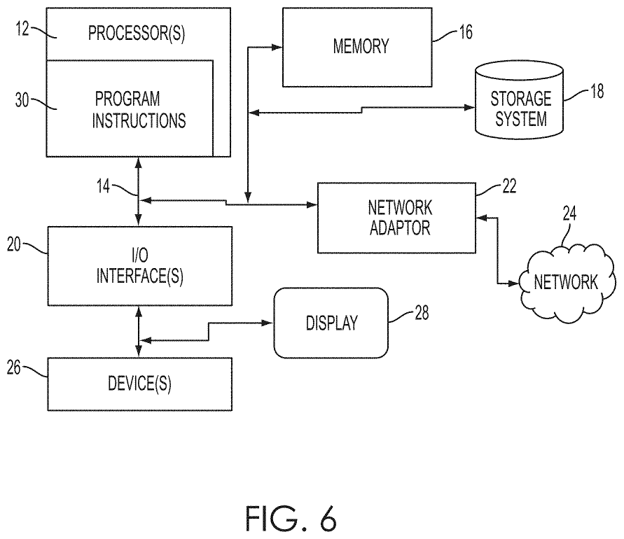

FIG. 6 illustrates a schematic of an example computer or processing system that may implement a system in one embodiment. The computer system is only one example of a suitable processing system and is not intended to suggest any limitation as to the scope of use or functionality of embodiments of the methodology described herein. The processing system shown may be operational with numerous other general purpose or special purpose computing system environments or configurations. Examples of well-known computing systems, environments, and/or configurations that may be suitable for use with the processing system shown in FIG. 6 may include, but are not limited to, personal computer systems, server computer systems, thin clients, thick clients, handheld or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

The computer system may be described in the general context of computer system executable instructions, such as program modules, being run by a computer system. Generally, program modules may include routines, programs, objects, components, logic, data structures, and so on that perform particular tasks or implement particular abstract data types. The computer system may be practiced in distributed cloud computing environments where tasks are performed by remote processing devices that are linked through a communications network. In a distributed cloud computing environment, program modules may be located in both local and remote computer system storage media including memory storage devices.

The components of computer system may include, but are not limited to, one or more processors or processing units 12, a system memory 16, and a bus 14 that couples various system components including system memory 16 to processor 12. The processor 12 may include a module 30 that performs the methods described herein. The module 30 may be programmed into the integrated circuits of the processor 12, or loaded from memory 16, storage device 18, or network 24 or combinations thereof.

Bus 14 may represent one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

Computer system may include a variety of computer system readable media. Such media may be any available media that is accessible by computer system, and it may include both volatile and non-volatile media, removable and non-removable media.

System memory 16 can include computer system readable media in the form of volatile memory, such as random access memory (RAM) and/or cache memory or others. Computer system may further include other removable/non-removable, volatile/non-volatile computer system storage media. By way of example only, storage system 18 can be provided for reading from and writing to a non-removable, non-volatile magnetic media (e.g., a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 14 by one or more data media interfaces.

Computer system may also communicate with one or more external devices 26 such as a keyboard, a pointing device, a display 28, etc.; one or more devices that enable a user to interact with computer system; and/or any devices (e.g., network card, modem, etc.) that enable computer system to communicate with one or more other computing devices. Such communication can occur via Input/Output (I/O) interfaces 20.

Still yet, computer system can communicate with one or more networks 24 such as a local area network (LAN), a general wide area network (WAN), and/or a public network (e.g., the Internet) via network adapter 22. As depicted, network adapter 22 communicates with the other components of computer system via bus 14. It should be understood that although not shown, other hardware and/or software components could be used in conjunction with computer system. Examples include, but are not limited to: microcode, device drivers, redundant processing units, external disk drive arrays, RAID systems, tape drives, and data archival storage systems, etc.

It is understood in advance that although this disclosure may include a description on cloud computing, implementation of the teachings recited herein are not limited to a cloud computing environment. Rather, embodiments of the present invention are capable of being implemented in conjunction with any other type of computing environment now known or later developed. Cloud computing is a model of service delivery for enabling convenient, on-demand network access to a shared pool of configurable computing resources (e.g. networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure that includes a network of interconnected nodes.

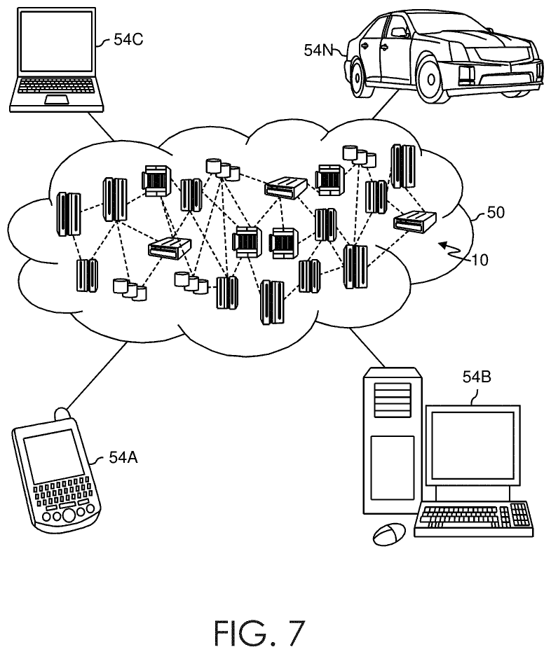

Referring now to FIG. 7, illustrative cloud computing environment 50 is depicted. As shown, cloud computing environment 50 includes one or more cloud computing nodes 10 with which local computing devices used by cloud consumers, such as, for example, personal digital assistant (PDA) or cellular telephone 54A, desktop computer 54B, laptop computer 54C, and/or automobile computer system 54N may communicate. Nodes 10 may communicate with one another. They may be grouped (not shown) physically or virtually, in one or more networks, such as Private, Community, Public, or Hybrid clouds as described hereinabove, or a combination thereof. This allows cloud computing environment 50 to offer infrastructure, platforms and/or software as services for which a cloud consumer does not need to maintain resources on a local computing device. It is understood that the types of computing devices 54A-N shown in FIG. 7 are intended to be illustrative only and that computing nodes 10 and cloud computing environment 50 can communicate with any type of computerized device over any type of network and/or network addressable connection (e.g., using a web browser).

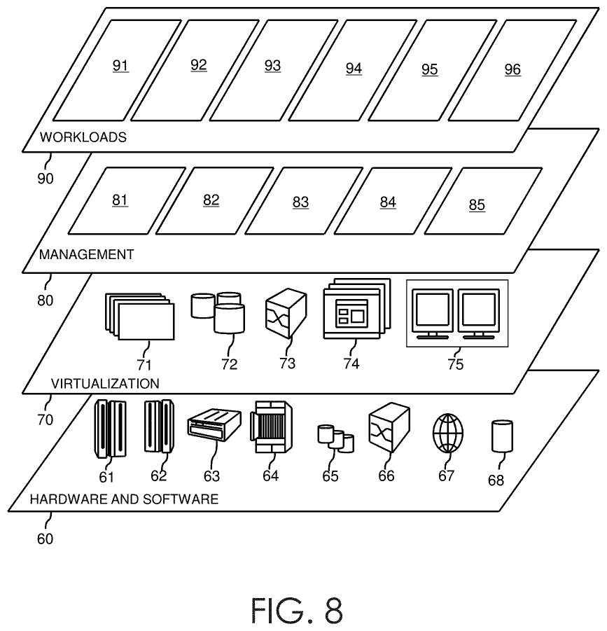

Referring now to FIG. 8, a set of functional abstraction layers provided by cloud computing environment 50 (FIG. 7) is shown. It should be understood in advance that the components, layers, and functions shown in FIG. 8 are intended to be illustrative only and embodiments of the invention are not limited thereto. As depicted, the following layers and corresponding functions are provided:

Hardware and software layer 60 includes hardware and software components. Examples of hardware components include: mainframes 61; RISC (Reduced Instruction Set Computer) architecture based servers 62; servers 63; blade servers 64; storage devices 65; and networks and networking components 66. In some embodiments, software components include network application server software 67 and database software 68.

Virtualization layer 70 provides an abstraction layer from which the following examples of virtual entities may be provided: virtual servers 71; virtual storage 72; virtual networks 73, including virtual private networks; virtual applications and operating systems 74; and virtual clients 75.

In one example, management layer 80 may provide the functions described below. Resource provisioning 81 provides dynamic procurement of computing resources and other resources that are utilized to perform tasks within the cloud computing environment. Metering and Pricing 82 provide cost tracking as resources are utilized within the cloud computing environment, and billing or invoicing for consumption of these resources. In one example, these resources may include application software licenses. Security provides identity verification for cloud consumers and tasks, as well as protection for data and other resources. User portal 83 provides access to the cloud computing environment for consumers and system administrators. Service level management 84 provides cloud computing resource allocation and management such that required service levels are met. Service Level Agreement (SLA) planning and fulfillment 85 provide pre-arrangement for, and procurement of, cloud computing resources for which a future requirement is anticipated in accordance with an SLA.

Workloads layer 90 provides examples of functionality for which the cloud computing environment may be utilized. Examples of workloads and functions which may be provided from this layer include: mapping and navigation 91; software development and lifecycle management 92; virtual classroom education delivery 93; data analytics processing 94; transaction processing 95; and intelligent model calibration processing 96.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, run concurrently, substantially concurrently, in a partially or wholly temporally overlapping manner, or the blocks may sometimes be run in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. As used herein, the term “or” is an inclusive operator and can mean “and/or”, unless the context explicitly or clearly indicates otherwise. It will be further understood that the terms “comprise”, “comprises”, “comprising”, “include”, “includes”, “including”, and/or “having,” when used herein, can specify the presence of stated features, integers, steps, operations, elements, and/or components, but do not preclude the presence or addition of one or more other features, integers, steps, operations, elements, components, and/or groups thereof. As used herein, the phrase “in an embodiment” does not necessarily refer to the same embodiment, although it may. As used herein, the phrase “in one embodiment” does not necessarily refer to the same embodiment, although it may. As used herein, the phrase “in another embodiment” does not necessarily refer to a different embodiment, although it may. Further, embodiments and/or components of embodiments can be freely combined with each other unless they are mutually exclusive.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A method performed by at least one hardware processor, the method comprising:
receiving a modeling problem to calibrate;
searching a database of prior calibrated models to identify a similar problem having features similar to the received modeling problem;
calibrating the modeling problem using information of the identified similar problem;
monitoring the accuracy of calibrated modeling problem;
recalibrating the modeling problem until a performance criterion is met; and
storing calibrated modeling problem in the database.

2. The method of claim 1, wherein the information includes statistical description of initial conditions and calibrated model results with parameter distributions.

3. The method of claim 1, further including generating the database of the prior calibrated models, the database storing statistical description of initial conditions and calibrated model results with parameter distributions associated with each of the prior calibrated models.

4. The method of claim 1, wherein said calibrating includes performing parameter reduction technique.

5. The method of claim 1, wherein said monitoring includes monitoring for convergence to an error threshold.

6. The method of claim 1, further including testing with historical results and tracking loss functions to determine performance of the calibrated modeling problem.

7. The method of claim 1, wherein the calibrated modeling problem includes disease modeling and an output of the calibrated modeling problem automatically triggers an air filtration system to circulate air in a space.

8. A system comprising:
at least one hardware processor; and
a memory device coupled with said at least one hardware processor;
said at least one hardware processor configured to at least:
receive a modeling problem to calibrate;
search a database of prior calibrated models to identify a similar problem having features similar to the received modeling problem;
calibrate the modeling problem using information of the identified similar problem;
monitor the accuracy of calibrated modeling problem;
recalibrate the modeling problem until a performance criterion is met; and
store calibrated modeling problem in the database.

9. The system of claim 8, wherein the information includes statistical description of initial conditions and calibrated model results with parameter distributions.

10. The system of claim 8, wherein said at least one hardware processor is further configured to generate the database of the prior calibrated models, the database storing statistical description of initial conditions and calibrated model results with parameter distributions associated with each of the prior calibrated models.

11. The system of claim 8, wherein said at least one hardware processor is configured to perform parameter reduction technique to calibrate the modeling problem.

12. The system of claim 8, wherein said at least one hardware processor is configured to monitor calibrating of the modeling problem for convergence to an error threshold.

13. The system of claim 8, wherein said at least one hardware processor is configured to test the calibrated modeling problem with historical results and track loss functions to determine performance of the calibrated modeling problem.

14. The system of claim 8, wherein an output of the calibrated modeling problem automatically triggers a physical barrier to open or close.

15. A computer program product comprising a computer readable storage medium having program instructions embodied therewith, the program instructions readable by a device to cause the device to:
receive a modeling problem to calibrate;
search a database of prior calibrated models to identify a similar problem having features similar to the received modeling problem;
calibrate the modeling problem using information of the identified similar problem;
monitor the accuracy of calibrated modeling problem;
recalibrate the modeling problem until a performance criterion is met; and
store calibrated modeling problem in the database.

16. The computer program product of claim 15, wherein the information includes statistical description of initial conditions and calibrated model results with parameter distributions.

17. The computer program product of claim 15, wherein the device is further caused to generate the database of the prior calibrated models, the database storing statistical description of initial conditions and calibrated model results with parameter distributions associated with each of the prior calibrated models.

18. The computer program product of claim 15, wherein the device is further caused to perform parameter reduction technique to calibrate the modeling problem.

19. The computer program product of claim 15, wherein the device is further caused to monitor calibrating of the modeling problem for convergence to an error threshold.

20. The computer program product of claim 15, wherein the device is further caused to test the calibrated modeling problem with historical results and track loss functions to determine performance of the calibrated modeling problem.
